(19) United States
(12) Patent Application Publication
(10) Pub. No.: US 2009/0051250 A1
(43) Pub. Date: Feb. 26, 2009

(54) Mesh Terminals For Piezoelectric Elements

(76) Inventors: Dushyant Shah, San Ramon, CA (US); Nickola S. Lewis, Fremont, CA (US)

Correspondence Address: ORRICK, HERRINGTON & SUTCLIFFE LLP, SUITE 1600, FOUR PARK PLAZA, IRVINE, CA, 92614-2558, US

(21) Appl. No.: 11/842,812

(22) Filed: Aug. 21, 2007

(51) Int. Cl. H01L 41/08

(52) U.S. Cl. 310/328

(57) ABSTRACT

The present invention provides systems and methods for connecting a coaxial cable or other conductor to an acoustic element, e.g., piezoelectric element, that withstand stress, e.g., due to vibrations of the piezoelectric element. In an embodiment, mesh terminals are bonded to the top and bottom of an piezoelectric element by conductive epoxy. Each mesh terminal has a mesh pattern comprising one or more openings through which the conductive epoxy flows and contacts the piezoelectric element thereby proving additional bonding areas for the epoxy to secure the mesh terminal to the piezoelectric element. This results in a stronger bond between the mesh terminal and the piezoelectric element. A coaxial cable or other conductor is connected to the piezoelectric element via the mesh terminal. The mesh terminal includes a stress relief element that reduces the amount of stress at a joint where the mesh terminal connects to the coaxial cable.

### FIELD OF THE INVENTION

The present invention relates to piezoelectric elements, and more particularly to mesh terminals for piezoelectric elements.

### BACKGROUND INFORMATION

Intravascular ultrasound imaging systems (IVUS) are used to obtain ultrasound images inside a patient's body. An IVUS system typically includes an ultrasound catheter having a flexible catheter body adapted for insertion into the vascular system of the patient. To obtain ultrasound images, the catheter comprises an imaging core received within a lumen of the catheter body. The imaging core comprises a piezoelectric crystal (PZT) element connected to the distal end of a flexible drive cable that is used to rotate and/or longitudinally translate the piezoelectric element within the catheter lumen. The piezoelectric element mechanically vibrates and emits ultrasound waves in response to an electrical signal applied to the piezoelectric element. The emitted ultrasound waves are reflected off of body tissue back to the piezoelectric element. The piezoelectric element converts the returning ultrasound waves into electrical signals, which are processed by an image processor to obtain an image of the patient. The imaging core typically comprises a coaxial cable running through the catheter lumen and connected to the piezoelectric element for transmitting electrical signals to and from the piezoelectric element.

A prior art approach for connecting the coaxial cable to the piezoelectric element is to lay a wire of the coaxial cable on top of the piezoelectric element and apply a conductive silver epoxy to the wire and top of the piezoelectric element to form a single point lap joint. This joint is placed under stress, e.g., during mechanical vibrations of the piezoelectric element. Under stress, the joint is very susceptible to cracking and separation due to the single point lap of the joint and lack of stress relief. In addition, materials surrounding the joint are hydroscopic in nature and swell with prolonged exposure to fluids during use. This swelling can also cause joint separation.

Therefore, there is a need for systems and methods for connecting coaxial cables or other conductors to piezoelectric elements that overcome the disadvantages of the prior art.

### SUMMARY OF THE INVENTION

The present invention provides systems and methods for connecting a coaxial cable or other conductor to an acoustic element, e.g., piezoelectric element, that are able to withstand greater stress, e.g., due to vibrations of the piezoelectric element.

In an embodiment, mesh terminals are bonded to the top and bottom of an piezoelectric element by a conductive epoxy. Each mesh terminal has a mesh pattern comprising one or more openings through which the epoxy flows and contacts the piezoelectric element proving additional bonding areas for the epoxy to secure the mesh terminal to the piezoelectric element. This results in a much stronger bond between the mesh terminal and the piezoelectric element compared with the single point lap joint of the prior art. Further, the mesh terminal provides a larger area of surface contact with the piezoelectric element. A coaxial cable or other conductor, e.g., twisted wire pair, is connected to the piezoelectric element by connecting wires of the coaxial cable to the mesh terminals, e.g., by solder joints.

In another embodiment, the mesh terminal includes a stress relief element in the form of a curved lead connected to a wire of the coaxial cable, e.g., by a solder joint. The curved lead dampens vibrations of the piezoelectric element so that the vibrations at the end of the lead connected to the wire are greatly reduced. As a result, the joint connecting the wire to the mesh terminal is subjected to much less stress.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE FIGURES

In order to better appreciate how the above-recited and other advantages and objects of the present inventions are objected, a more particular description of the invention briefly described above will be rendered by reference to specific embodiments thereof, which are illustrated in the accompanying drawings. It should be noted that the components in the figures are not necessarily to scale, emphasis instead being placed upon illustrating the principles of the invention. Moreover, in the figures, like reference numerals designate corresponding parts throughout the different views. However, like parts do not always have like reference numerals. Moreover, all illustrations are intended to convey concepts, where relative sizes, shapes and other detailed attributes may be illustrated schematically rather than literally or precisely.

FIG. 1a shows an exploded perspective view of a transducer assembly according to an example embodiment of the invention.

FIG. 1b shows a top perspective view of a mesh terminal according to an example embodiment of the invention.

FIG. 1c shows a cross-section view of the mesh terminal bonded to an electrode of a piezoelectric element according to an example embodiment of the invention.

FIG. 2 shows a perspective view of a mesh terminal having a stress relief element according to another example embodiment of the invention.

FIG. 3 shows a perspective view of a mesh terminal according to yet another embodiment of the invention.

FIGS. 4-8 show top views of additional mesh terminals according to other example embodiments of the invention.

FIGS. 9-17 show bottom mesh terminals according to other example embodiments of the invention.

### DETAILED DESCRIPTION

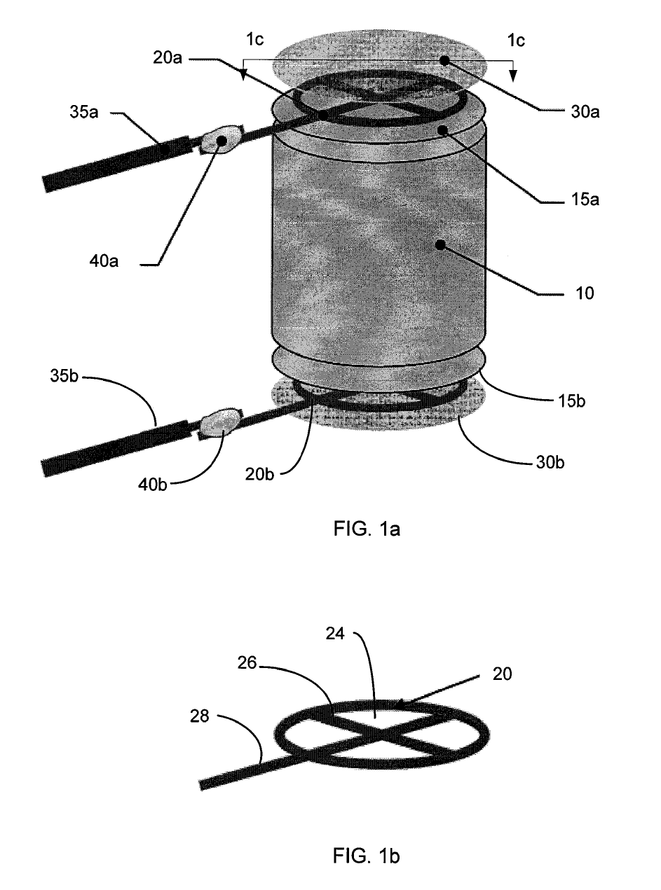

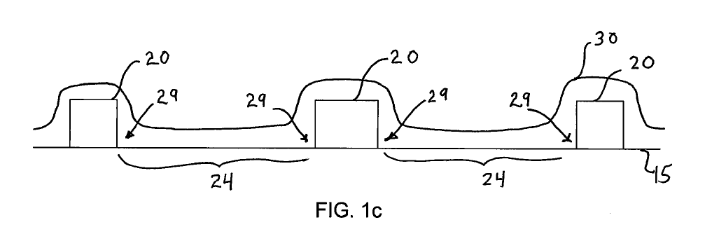

FIG. 1a shows an exploded perspective view of an exemplary transducer assembly according to an embodiment of the invention. The transducer assembly comprises a piezoelectric element 10, and top and bottom electrodes 15a and 15b on the top and bottom of the piezoelectric element 10, respectively. The top and bottom electrodes 15a and 15b are used to apply an electrical signal, e.g., voltage, across the piezoelectric element 10 to cause the piezoelectric element 10 to vibrate and emit ultrasound waves. The top and bottom electrodes 15a and 15b may be formed by applying a layer of metal, e.g., gold, to the top and bottom of the piezoelectric element 10. Other acoustic elements may used instead of piezoelectric elements.

The transducer assembly further comprises top and bottom electrode mesh terminals 20a and 20b. Each mesh terminal 20 has a generally circular perimeter matching the circular shape of the respective electrode 15, and a mesh pattern comprising a plurality of openings. FIG. 1b shows a perspective top view of one of the mesh terminals 20. In the example shown in FIG. 1b, each mesh terminal 20 has a mesh pattern comprising four openings 24 forming a cross shape 26 therebetween. Each mesh terminal 20a, 20b further comprises an elongated lead 28 that is connected to a wire 35a, 35b of a coaxial cable or other conductor by, e.g., a solder joint 40a, 40b, which are shown in FIG. 1a. The wire 35a, 35b can also be ultrasonically bonded to the respective mesh terminal 20a, 20b. In the preferred embodiment, each mesh terminal 20a, 20b is etched from a single piece of metal. Details of etching processes that can be used to form the mesh terminals are given below. Although the piezoelectric element 10 is shown having a cylindrical shape in FIG. 1a, the piezoelectric element can have other shapes.

The transducer assembly further comprises a top and bottom layer of conductive epoxy 30a, 30b, e.g., silver epoxy. The top layer of conductive epoxy 30a is applied over the top mesh terminal 20a to bond the top mesh terminal 20a to the top electrode 15a. FIG. 1c shows a cross-sectional view taken along line 1c-1c in FIG. 1a after the top layer of conductive epoxy 30a has been applied. The conductive epoxy 30 flows through the openings 24 of the mesh terminal 20 (e.g., 20a, 20b) and contacts the electrode 15 (e.g., 15a, 15b) through the openings 24 providing additional bonding areas 29 for the epoxy to secure the mesh terminal 20 to the electrode 15. This provides a much stronger bond between the mesh terminal 20 and the electrode 15 compared with a single point lap joint of the prior art. As a result, the bond between the mesh terminal 20 and electrode 15 is able to withstand greater vibrations of the piezoelectric element 10 and other stresses without separating. Further, the mesh terminal 20 provides a larger area for applying the epoxy 30, which helps produce more consistently reliable bonds, and a larger area of surface contact with the piezoelectric element. The bottom layer of conductive epoxy 30b is similarly applied to the bottom mesh terminal 20b and bottom electrode 15b to bond the bottom mesh terminal 20b to the bottom electrode 15b. In this embodiment, the top mesh terminal 20a can serve as a positive contact lead for the transducer and the bottom mesh terminal 20b can serve as a negative contact lead for the transducer. The top and bottom mesh terminals 20a and 20b can also be bonded to the piezoelectric element 10 without the intervening top and bottom electrodes 15a and 15b.

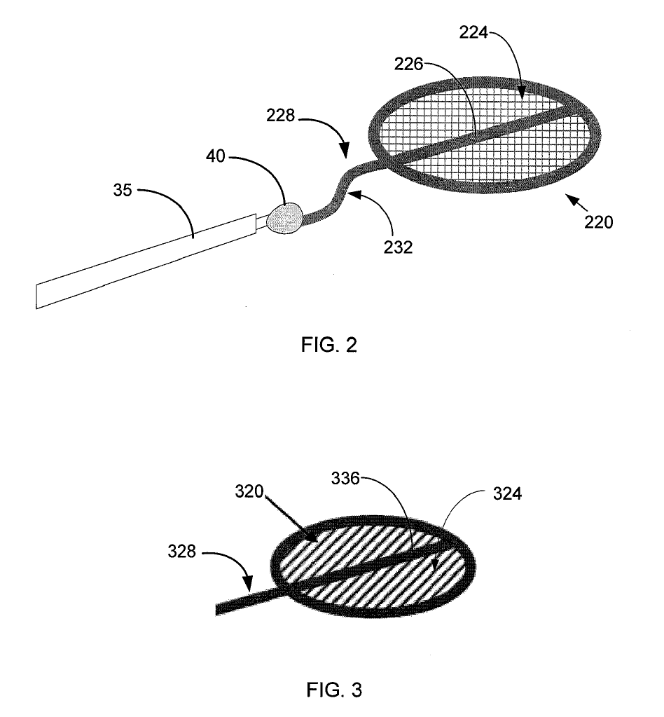

FIG. 2 shows a mesh terminal 220 according to another exemplary embodiment, in which the mesh pattern comprises an array of small square openings 224 with a bar 226 running across the mesh terminal 220. The lead 228 of the mesh terminal 220 has a curved portion 232 to provide stress relief for the joint 40 between the wire 35 and the mesh terminal 220. In the example embodiment shown in FIG. 2, the portions of the lead 228 on either side of the curved portion 232 run parallel to each other. The curved portion 232 allows the lead 228 to dampen vibrations from the piezoelectric element 20 so that stress is greatly reduced at the end of the lead 228 connected to the wire 35. As a result, the joint 40 connecting the wire 35 to the mesh terminal 220 is subjected to much less stress compared with the prior art, in which the wire is directly bonded to the piezoelectric element by a single point lap joint. The curved lead 228 can optionally be used in any embodiment of the present invention to provide stress relief, including the embodiment shown in FIGS. 1a-1c. Other curvatures can be used besides the one shown in FIG. 2.

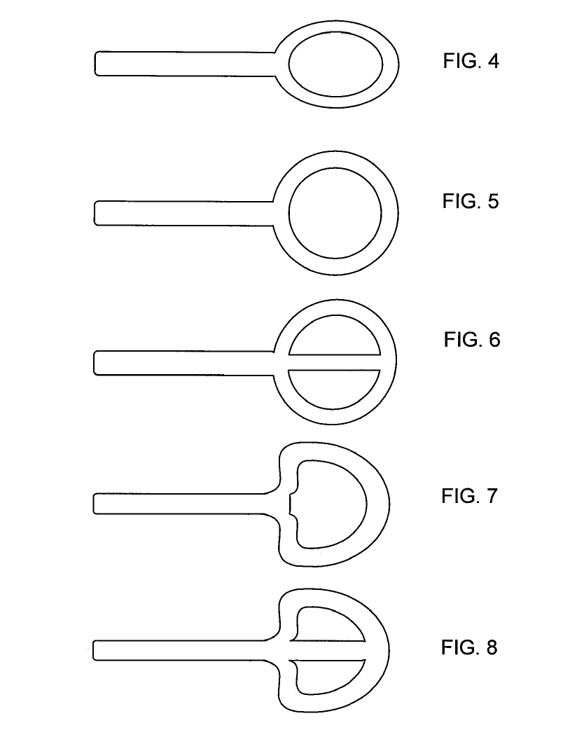

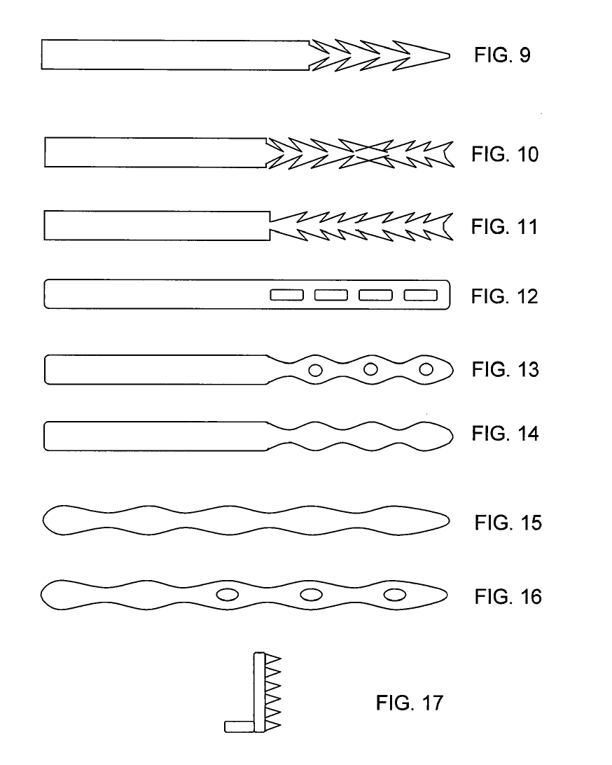

FIG. 3 shows a mesh terminal 320 according to another exemplary embodiment of the invention, in which the mesh pattern comprises a plurality of narrow openings 324 or slots with a bar 336 running across the mesh terminal 320 and aligned with the projection 328. FIGS. 4-8 show top views of additional exemplary embodiments of the mesh terminal. FIGS. 9-17 show exemplary embodiments of the bottom or negative mesh terminal. The above example embodiments are intended only to aid in the illustration of the various configurations that are possible for the mesh terminal. Since a large number of configurations are possible for the mesh terminal, it is not intended that the mesh terminal be limited to the example embodiments described or depicted herein.

A matching layer (not shown) may be placed over the top mesh terminal to improve piezoelectric coupling between the piezoelectric element and surrounding tissue or fluid by matching the piezoelectric impedance of the transducer with that of the surrounding tissue or fluid. This matching provides for the efficient transmission of ultrasound signals at the interface between the transducer and the surrounding tissue or fluid. In an embodiment, the top mesh terminal can be used as the matching layer to provide the piezoelectric impedance matching. The advantage of this embodiment is that a separate matching layer is not needed to provide the piezoelectric impedance matching. In this embodiment, the mesh terminal has a thickness that is approximately one quarter the wavelength of the ultrasound waves emitted by the piezoelectric element. This results in the impedance of the surrounding tissue or fluid appearing to be the same as the piezoelectric element at the piezoelectric element. Preferably, a dense mesh terminal is used for the matching layer, e.g., a mesh terminal having a pattern of many small or narrow openings, e.g., the mesh terminal shown in FIG. 2 or 3.

A backing layer (not shown) may be placed on the bottom of the piezoelectric element and bottom mesh terminal to attenuate piezoelectric energy that propagates from the bottom of the piezoelectric element and to direct emission of ultrasound waves from the top of the transducer. The backing layer may also be placed directly on the bottom of the piezoelectric element with the bottom mesh terminal bonded to the back of the backing layer. In this embodiment, the backing layer is made of a conductive material so that electrical signals can pass through the backing layer. In another embodiment, the bottom mesh terminal can be in the form of a conductive ring that is placed around the circumference of the backing layer and bonded to the backing layer, e.g., by a conductive epoxy, for the negative contact lead.

Methods for fabricating a mesh terminal will now be described. The mesh terminal can be etched from a metal piece or other conductive material using a photo-chemical etching process. For example, a Photochemical Milling (PCM) process can be used to photo-chemically etch the mesh terminal from a metal piece. A PCM process uses photolithography similar to photolithography used to etch semiconductors, e.g., silicon, to produce microcircuits or micro-size parts from different base metals. Base metals that can be used to fabricate the mesh terminal include, but are not limited to, stainless steel, beryllium, copper, copper alloys, brass, nickel, NiTinol, gold plated NiTinol, and the like.

The mesh terminal can also be fabricated by electrochemical machining (ECM) and photochemical machining processes that use etching, electrochemical, and photochemical processes to create unstressed, high-precision parts. An ECM process is based on a controlled, anodic dissolution of a work piece (anode electrode) using a tool (cathode electrode) in an electrolytic solution. To achieve electrolysis, an electric current is passed between the anode and cathode electrodes. The resulting electrochemical reaction dissolves the metallic ions at the anode surface of the work piece and copies the tool's (cathode's) shape into the work piece. Photochemical machining is similar to ECM, but can remove metal by either etching or an electrochemical reaction. With photochemical machining, the resulting parts have a high tolerance and precise shape. Other processes that may be performed by electrochemical and photochemical machining include electrochemical milling, electrochemical machining, chemical blanking, photomilling, and photomachining.

There is a wide variety of etchants that can be used to etch a metal piece into the mesh terminal. For example, a ferric chloride solution can be used as the etchant. Preferably, the etching process does not alter the internal structure of the metal used to fabricate the mesh terminal so that the internal structure of the metal, including its harness, grain structure and ductility, remain unchanged.

In the foregoing specification, the invention has been described with reference to specific embodiments thereof. It will, however, be evident that various modifications and changes may be made thereto without departing from the broader spirit and scope of the invention. For example, the reader is to understand that the specific ordering and combination of process actions described herein is merely illustrative, and the invention can be performed using different or additional process actions, or a different combination or ordering of process actions. As a further example, each feature of one embodiment can be mixed and matched with other features shown in other embodiments. Additionally and obviously, features may be added or subtracted as desired. Accordingly, the invention is not to be restricted except in light of the attached claims and their equivalents.

What is claimed is:

1. A transducer assembly, comprising:
a piezoelectric element;
a mesh terminal having one or more openings and a lead, wherein the mesh terminal is located on a surface of the piezoelectric element; and
a layer of conductive epoxy over the mesh terminal, wherein the layer of conductive epoxy contacts the piezoelectric element around a perimeter of the mesh terminal and through the one or more openings of the mesh terminal.

2. The transducer assembly of claim 1, wherein the mesh terminal comprises at least two openings.

3. The transducer assembly of claim 1, wherein the mesh terminal comprises at least four openings.

4. The transducer assembly of claim 1, further comprising:
a second mesh terminal having one or more openings and a second lead, wherein the second mesh terminal is located on a surface of the piezoelectric element opposite that of the first mesh terminal; and
a second layer of conductive epoxy over the second mesh terminal, wherein second layer of conductive epoxy contacts the piezoelectric element around a perimeter of the second mesh terminal and through the one or more openings of the second mesh terminal

5. The transducer assembly of claim 4, wherein the first mesh terminal comprises at least two openings.

6. The transducer assembly of claim 4, wherein the first mesh terminal comprises at least four openings.

7. The transducer assembly of claim 4, wherein each one of the first and second mesh terminals comprises at least two openings.

8. The transducer assembly of claim 4, wherein each one of the first mesh terminals comprises at least four openings.

9. The transducer assembly of claim 1, wherein the piezoelectric element comprises an electrode contacting the mesh terminal.

10. The transducer assembly of claim 1, wherein the lead of the mesh terminal is elongated and has a curved portion for providing stress relief.

11. The transducer assembly of claim 10, wherein the lead has a first portion and a second portion on opposite sides of the curved portion, and the first and second portions run substantially parallel to each other.

12. The transducer assembly of claim 10, further comprising a wire connected to an end of the lead.

13. The transducer assembly of claim 12, wherein the wire is connected to the end of the lead by a solder joint.

14. The transducer assembly of claim 1, wherein the mesh terminal has a thickness of approximately one quarter of a wavelength of ultrasound waves emitted by the piezoelectric element.
